(19) United States
(12) Patent Application Publication
(10) Pub. No.: US 2019/0157527 A1
(43) Pub. Date: May 23, 2019

(54) LIGHT EMITTING ELEMENT PACKAGE

(71) Applicant: GM GLOBAL TECHNOLOGY OPERATIONS LLC, DETROIT, MI (US)

(72) Inventors: Jonglee Park, Troy, MI (US); Jeffrey T. Zawacki, Oxford, MI (US)

(21) Appl. No.: 15/820,764

(22) Filed: Nov. 22, 2017

(51) Int. Cl. H01L 33/58; H01L 25/075; H01L 33/62; H01L 33/56; H01L 33/50; H01L 33/60; H01L 23/538; G02B 3/08

(52) U.S. Cl. CPC H01L 33/58; H01L 25/0753; H01L 33/62; G02B 3/08; H01L 33/502; H01L 33/60; H01L 23/5387; H01L 33/56

(57) ABSTRACT

A light emitting diode apparatus is provided. The light emitting diode apparatus includes: a substrate comprising a conductive pattern, a plurality of light emitting diode packages disposed on the conductive pattern, and a lens molded onto the plurality of light emitting diodes packages, the lens comprising a refractive optic pattern molded into the lens.

### INTRODUCTION

Apparatuses and methods consistent with exemplary embodiments relate to light emitting elements. More particularly, apparatuses and methods consistent with exemplary embodiments relate to packages of light emitting elements.

### SUMMARY

One or more exemplary embodiments provide a linear package of light emitting elements. More particularly, one or more exemplary embodiments provide a linear package of light emitting elements disposed on a substrate that is at least partially flexible.

According to an exemplary embodiment, a light emitting element apparatus is provided. The apparatus includes a substrate comprising a conductive pattern, a plurality of light emitting element packages disposed on the conductive pattern, and an encapsulant molded onto the plurality of light emitting element packages, the encapsulant comprising a refractive optic pattern molded into the encapsulant.

The refractive optic pattern may include at least one from among a flute pattern and a Fresnel optic pattern.

The substrate may include a plurality of first areas that are rigid connected by a plurality of second areas that are flexible.

The plurality of first areas may be larger in area than the plurality of second areas.

The plurality of first areas may include at least one from among a rectangular area, a square area, a circular area, and an elliptical area, and the plurality of second areas may include a linear area.

The substrate may be flexible. Tach of the plurality of light emitting element packages may include a light emitting diode and a plurality of contacts.

The conductive pattern may include an anode and a cathode printed onto the substrate.

The encapsulant may include silicon and phosphor.

The substrate may include a flexible printed circuit board

According to an exemplary embodiment, a light emitting element apparatus is provided. The apparatus includes a flexible substrate comprising a conductive pattern, a plurality of light emitting element packages disposed on the conductive pattern, and a reflector disposed on the flexible substrate configured to reflect light emitting from the plurality of light emitting element packages.

The apparatus may include an encapsulant molded onto the plurality of light emitting element packages, the encapsulant including a refractive optic pattern molded into the encapsulant.

The refractive optic pattern may include at least one from among a flute pattern and a Fresnel optic pattern.

The flexible substrate may include a plurality of first areas that are rigid connected by a plurality of second areas that are flexible.

The plurality of first areas may be larger in area than the plurality of second areas.

The plurality of first areas may include at least one from among a rectangular area, a square area, a circular area, and an elliptical area, and the plurality of second areas comprise a linear area.

Each of the plurality of light emitting element packages may include a light emitting diode and a plurality of contacts.

The conductive pattern may include an anode and a cathode printed onto the substrate and the encapsulant may include silicon and phosphorous.

The substrate may include a flexible printed circuit board.

Other objects, advantages and novel features of the exemplary embodiments will become more apparent from the following detailed description of exemplary embodiments and the accompanying drawings.

### BRIEF DESCRIPTION OF THE DRAWINGS

FIG. 1 shows a diagram of a light emitting element apparatus according to an exemplary embodiment;

FIG. 2 shows a diagram of a conductive pattern on a substrate of a light emitting element apparatus according to an aspect of an exemplary embodiment;

FIG. 3 shows illustrations of example substrate designs of a light emitting element apparatus according to an exemplary embodiment;

FIG. 4 shows a diagram of a light emitting element apparatus according to another exemplary embodiment; and

FIG. 5 shows an illustration of a direction light emitting by light emitting element apparatus according to an aspect of an exemplary embodiment.

### DETAILED DESCRIPTION

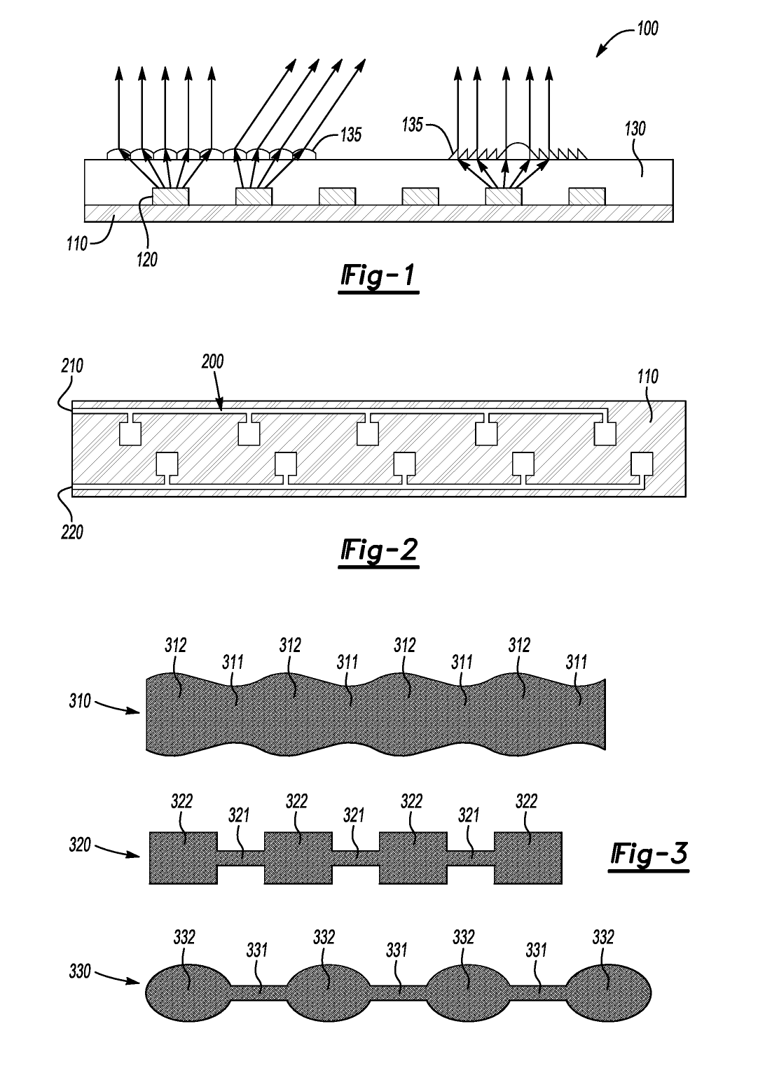

A light emitting element apparatus will now be described in detail with reference to FIGS. 1-5 of the accompanying drawings in which like reference numerals refer to like elements throughout.

The following disclosure will enable one skilled in the art to practice the inventive concept. However, the exemplary embodiments disclosed herein are merely exemplary and do not limit the inventive concept to exemplary embodiments described herein. Moreover, descriptions of features or aspects of each exemplary embodiment should typically be considered as available for aspects of other exemplary embodiments.

It is also understood that where it is stated herein that a first element is “connected to,” “attached to,” “formed on,” or “disposed on” a second element, the first element may be connected directly to, formed directly on or disposed directly on the second element or there may be intervening elements between the first element and the second element, unless it is stated that a first element is “directly” connected to, attached to, formed on, or disposed on the second element. In addition, if a first element is configured to “send” or “receive” information from a second element, the first element may send or receive the information directly to or from the second element, send or receive the information via a bus, send or receive the information via a network, or send or receive the information via intermediate elements, unless the first element is indicated to send or receive information “directly” to or from the second element.

Throughout the disclosure, one or more of the elements disclosed may be combined into a single device or combined into one or more devices. In addition, individual elements may be provided on separate devices.

Light emitting elements such as light emitting diodes (LEDs) are being incorporated into illumination devices and systems because they consume less energy than other light emitting devices. The light emitting element may be any that emits radiation within a desired wavelength region such as a visible wavelength region, an infrared wavelength region or an ultraviolet wavelength region. A light emitting element package may include a light emitting element such as a light emitting diode, two contacts, and a binder or an encapsulant that encapsulates the light emitting element.

An issue with that arises with light emitting elements is that there may be uniformity and distribution issues with the emissions of the light emitting elements. Thus, a binder or encapsulant that is configured to increase uniformity of the emissions of the light emitting element or distribute the emissions of the light emitting element according to mandated regulations increases the usefulness of light emitting elements.

FIG. 1 shows a diagram of a light emitting element apparatus according to an exemplary embodiment. Referring to FIG. 1, the light emitting apparatus may include a substrate 110, a plurality of light emitting elements 120, an encapsulant (i.e., a binder) 130 and a refractive pattern 135 molded into the encapsulant 130.

The substrate 110 may be a flexible printed circuit board and may include flexible portions and rigid portions. The substrate 110 may include conductive patterns printed on the substrate using conductive material such as gold, silver, or other metal. In addition, the substrate 110 may be designed according to a pattern, examples of which are shown in FIG. 3 below.

The plurality of light emitting elements 120 may include light emitting diodes. However, the plurality of light emitting elements may also include an element that emits radiation within a desired wavelength region such as a visible wavelength region, an infrared wavelength region or an ultraviolet wavelength region.

The encapsulant 130 may include silicon and phosphor. The encapsulant 130 may encapsulate the light emitting elements 120 such that all light emitting by the light emitting elements 120 travels through the encapsulant 130. The encapsulant 130 may be fixed to the substrate 110 and plurality of light emitting elements 120 by molding the encapsulant 130 onto the substrate 110 and plurality of light emitting elements 120.

The refractive pattern 135 may be integral with the encapsulant 130 and/or molded into or etched into the encapsulant 130. The refractive pattern 135 may include a pattern that refracts light or controls the directivity or direction of light so that the distribution of light complies with regulations or desired specifications. The refractive pattern 135 may include Fresnel optics configured to project light from the plurality of light emitting elements in a desired direction, for example, a direction parallel to the optical axis. The refractive pattern 135 may include flutes configured to project light from the plurality of light emitting elements in a desired direction, for example, a direction parallel to the optical axis.

FIG. 2 shows a diagram of a conductive pattern on a substrate of a light emitting element apparatus according to an aspect of an exemplary embodiment. Referring to FIG. 2, the substrate 110 may include a conductive pattern 200. The conductive pattern may include an anode pattern 210 and a cathode pattern 220. The conductive pattern may be printed onto the substrate using a conductive ink or conductive material such as gold, silver, or other metal

FIG. 3 shows illustrations of example substrate designs of a light emitting element apparatus according to an exemplary embodiment. Referring to FIG. 3, the substrate 110 of may be designed according to one or more patterns. The patterns may include a repeating pattern of a first area and a second area. The first area may be larger than the second area. Examples of substrate patterns are shown by substrate 310, substrate 320, and substrate 330.

Substrate 310 includes a repeating pattern of a first area 312 that is larger than a narrower area 311. Substrate 320 also includes a repeating pattern of a first area 322 that is larger than a narrower area 321. In addition, the first area 322 has a square shape and the second area 321 has a linear or rectangular shape. Substrate 330 also includes a repeating pattern of a first area 332 that is larger than a narrower area 331. In addition, the first area 332 has an elliptical or circular shape and the second area 321 has a linear or rectangular shape.

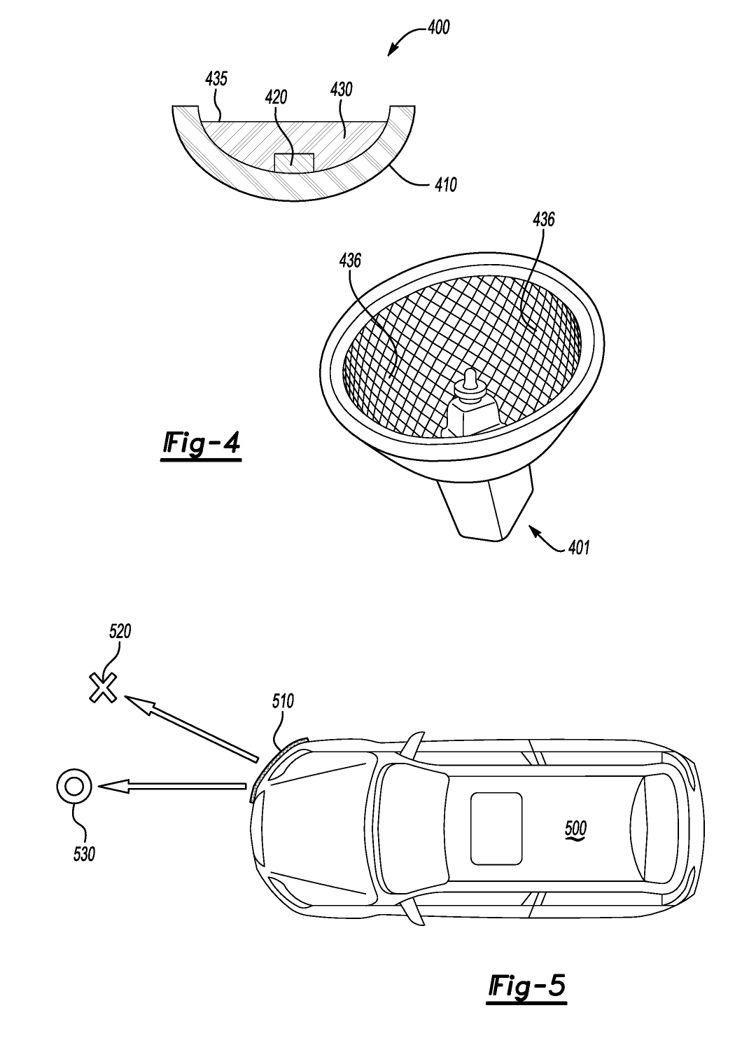

FIG. 4 shows a diagram of a light emitting element apparatus according to another exemplary embodiment. Referring to FIG. 4, the light emitting apparatus 400 may include a substrate 410, a plurality of light emitting elements 420, an encapsulant (i.e., a binder) 430 and a refractive pattern (not shown) molded into the encapsulant 430. In addition, the light emitting apparatus 400 may include a reflector or reflective coating 435 disposed on the substrate 410.

The substrate 410 may be a flexible printed circuit board and may include flexible portions and rigid portions. The substrate 410 may include conductive patterns printed on the substrate using conductive material such as gold, silver, or other metal. In addition, the substrate 410 may be designed according to a pattern, examples of which are shown in FIG. 3 above. In FIG. 4, the substrate 410 is molded or shaped to achieve the desired optic design or specification.

The plurality of light emitting elements 420 may include light emitting diodes. However, the plurality of light emitting elements may also include an element that emits radiation within a desired wavelength region such as a visible wavelength region, an infrared wavelength region or an ultraviolet wavelength region.

The encapsulant 430 may include silicon and phosphor. The encapsulant 430 may encapsulate the light emitting elements 420 such that all light emitting by the light emitting elements 420 travels through the encapsulant 430. The encapsulant 130 may be fixed to the substrate 410 and plurality of light emitting elements 420 by molding the encapsulant 430 onto the deformed substrate 410 and plurality of light emitting elements 420.

The reflector or reflective coating 435 may be a chrome coating or other coating used for specular reflectance. The reflective coating 435 may be disposed or painted onto the substrate 410 or may be adhered to the substrate 410. The reflector or reflective coating 435 may comprise a parabolic reflector or a multi-faced reflector. The reflector or reflective coating 435 may cause light reflected off its surface such that the incident angle of light traveling to the reflective surface is equal to the incident angle of the light being reflected from the reflective surface.

FIG. 5 shows an illustration of a direction light emitting by light emitting element apparatus according to an aspect of an exemplary embodiment. Referring to FIG. 5, a vehicle 500 may be equipped with a linear light emitting element apparatus 510. The linear light emitting element apparatus 510 may comprise the shape of a line and include a plurality of light emitting elements arranged linearly.

When the linear light emitting element apparatus 510 does not incorporate the refractive patterns 135 or reflector 435 described above, the light emitted by the light emitting element apparatus 510 may be directed to a position 520. This result may not be desirable. By incorporating refractive patterns 135 or reflector 435, the light emitted by the light emitting element apparatus 510 may be directed to a position 530 and comply with regulations and/or desired specifications.

One or more exemplary embodiments have been described above with reference to the drawings. The exemplary embodiments described above should be considered in a descriptive sense only and not for purposes of limitation. Moreover, the exemplary embodiments may be modified without departing from the spirit and scope of the inventive concept, which is defined by the following claims.

1. A light emitting element apparatus, the light emitting element apparatus comprising:
a substrate comprising a conductive pattern;
a plurality of light emitting element packages disposed on the conductive pattern; and
an encapsulant molded onto the plurality of light emitting element packages, the encapsulant comprising a refractive optic pattern molded into the encapsulant,
wherein the substrate comprises a plurality of first areas connected by a plurality of second areas,
wherein the plurality of first areas are larger in area than the plurality of second areas,
wherein the plurality of first areas are rigid connected and the plurality of second areas are flexible,
wherein the refractive optic pattern comprises at least one from among a flute pattern and a Fresnel optic pattern, and
wherein the plurality of first areas comprise at least one from among a circular area and an elliptical area, and the plurality of second areas comprise a linear area.

2. (canceled)

3. (canceled)

4. (canceled)

5. (canceled)

6. The light emitting element apparatus of claim 1, wherein the substrate is flexible.

7. The light emitting element apparatus of claim 1, wherein each of the plurality of light emitting element packages comprises a light emitting diode and a plurality of contacts.

8. The light emitting element apparatus of claim 1, wherein the conductive pattern comprises an anode and a cathode printed onto the substrate.

9. The light emitting element apparatus of claim 1, wherein the encapsulant comprises silicon and phosphor.

10. The light emitting element apparatus of claim 1, wherein the substrate comprises a flexible printed circuit board.

11. A light emitting element apparatus, the light emitting element apparatus comprising:
a flexible substrate comprising a conductive pattern;
a plurality of light emitting element packages disposed on the conductive pattern; and
a reflector disposed on the flexible substrate configured to reflect light emitting from the plurality of light emitting element packages; and
an encapsulant molded onto the plurality of light emitting element packages, the encapsulant comprising a refractive optic pattern molded into the encapsulant,
wherein the flexible substrate comprises a plurality of first areas connected by a plurality of second areas,
wherein the plurality of first areas are larger in area than the plurality of second areas,
wherein the plurality of first areas are rigid connected and the plurality of second areas are flexible,
wherein the refractive optic pattern comprises at least one from among a flute pattern and a Fresnel optic pattern, and
wherein the plurality of first areas comprise at least one from among a circular area and an elliptical area, and the plurality of second areas comprise a linear area.

12. (canceled)

13. (canceled)

14. (canceled)

15. (canceled)

16. (canceled)

17. The light emitting element apparatus of claim 11, wherein each of the plurality of light emitting element packages comprises a light emitting diode and a plurality of contacts.

18. The light emitting element apparatus of claim 11, wherein the conductive pattern comprises an anode and a cathode printed onto the flexible substrate.

19. The light emitting element apparatus of claim 11, wherein the encapsulant comprises silicon and phosphorous.

20. The light emitting element apparatus of claim 11, wherein the flexible substrate comprises a flexible printed circuit board.
